(19) United States
(12) Patent Application Publication
(10) Pub. No.: US 2023/0368950 A1
(43) Pub. Date: Nov. 16, 2023

(54) PACKAGING STRUCTURE WITH MAGNETOCALORIC MATERIAL

(71) Applicant: Potens Semiconductor Corp., Zhubei City (TW)

(72) Inventors: Wen Nan Huang, Zhubei City (TW); Ching Kuo Chen, Zhubei City (TW); Chih Ming Yu, Zhubei City (TW); Hsiang Chi Meng, Zhubei City (TW); I Ming Lo, Zhubei City (TW)

(21) Appl. No.: 17/742,153

(22) Filed: May 11, 2022

(51) Int. Cl. H01F 1/01; H01L 23/31; H01L 23/29

(52) U.S. Cl. CPC H01F 1/015; H01L 23/3121; H01L 23/293

(57) ABSTRACT

A packaging structure with a magnetocaloric material, comprising a substrate, a plurality of electrical connection structures, a die, and a sealing compound. A magnetocaloric material is added to the substrate. The die is electrically connected to the substrate through the electrical connection structures, and then encapsulated with the sealing compound. When the packaging structure is turned on, the magnetocaloric material in the substrate creates a magnetocaloric effect, which can not only take away the temperature of the packaging structure through magnetic refrigeration, but also increase the temperature difference between the packaging structure and the outside, thereby improving the efficiency of heat dissipation.

### BACKGROUND OF INVENTION

### (1) Field of the Present Disclosure

The present disclosure relates to a packaging structure with a magnetocaloric material.

### (2) Brief Description of Related Art

The semiconductor package is one of the most important processes at the back end of the transistor manufacturing process. After the semiconductor element core or the integrated circuit is etched from the wafer and cut into independent dies, one or several dies are integrated with the semiconductor package in the packaging stage to provide impact resistance and water resistance for the dies. At the same time, the electrical contacts of the die are also connected to the pins or contacts of the external circuit through the packaging process. Due to the continuous improvement of semiconductor process technology and on the basis of transistor performance growth and size reduction, multi-functional transistors have gradually become mainstream. For example, processors, memories, logic operation units, etc. can be integrated into a single transistor, or transistors with different functions can be heterogeneously integrated by means of 2.5-dimensional or 3-dimensional packaging structures; and the aforementioned are widely used. Whether the aforementioned packaging method is widely used, or an advanced packaging method that has the potential to continue Moore's Law, it is necessary to consider good heat dissipation efficiency. Regardless of whether the aforementioned packaging method is a widely used packaging method, or the aforementioned packaging method is an advanced packaging method having the potential to continue Moore's Law, good heat dissipation efficiency must be considered. The relevant disclosures are such as: Patent Publication No. TW202103277A, which employs graphite materials to improve heat dissipation efficiency, and Patent Publication No. CN213459708U, Patent Publication No. CN213304111U, etc. However, in order to cope with the ever-increasing performance and decreasing volume of transistor chips, the heat dissipation structure still needs to be improved. Accordingly, how to effectively increase the heat dissipation efficiency of the package structure under the original package structure is a problem to be solved.

### SUMMARY OF INVENTION

It is a primary object of the present disclosure to provide a packaging structure with magnetocaloric material that utilizes the magnetic refrigeration effect to effectively improve the heat dissipation efficiency

According to the present disclosure, a magnetocaloric material, such as Gd₂O₃, Gd₅Ge₂Si₂, and other materials, is added into the substrate, so that when the packaging structure is turned on, the magnetic refrigeration effect created by the magnetocaloric effect can help the die in the packaging structure to dissipate heat. Under the original packaging structure, the heat dissipation efficiency of the package structure can be effectively increased.

### BRIEF DESCRIPTION OF THE DRAWINGS

FIG. 1 is a schematic drawing of a packaging structure according to the present disclosure;

FIG. 2 is an implementation view of the present disclosure;

FIG. 3 is a schematic drawing of a first embodiment of the present disclosure;

FIG. 4 is a schematic drawing of a second embodiment of the present disclosure;

FIG. 5 is a schematic drawing of a third embodiment of the present disclosure; and

FIG. 6 is a comparison table of the operation temperature of the present disclosure.

### DETAILED DESCRIPTION OF PREFERRED EMBODIMENTS

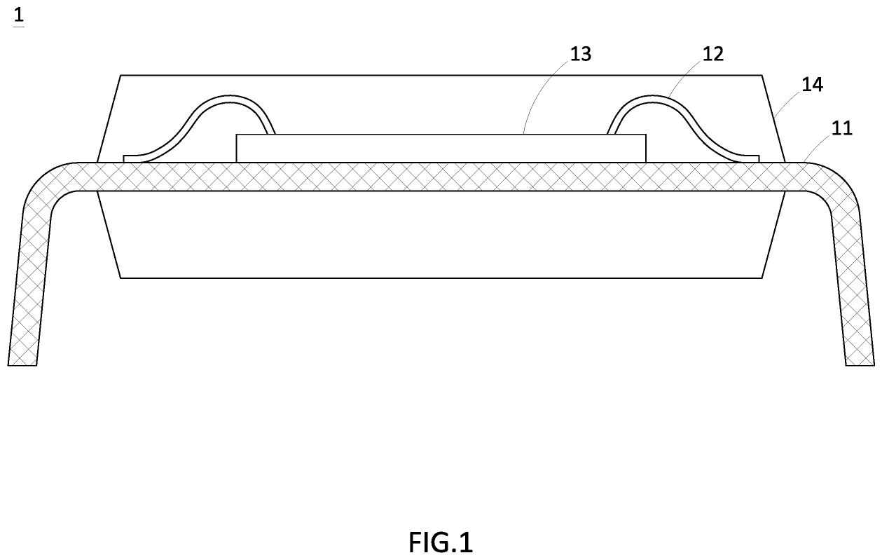

Referring to FIG. 1, a packaging structure with a magnetocaloric material of the present disclosure includes a substrate 11, an electrical connection structure 12, a die 13, and a sealing compound 14. each component is exemplified and described below. Moreover, the electrical connection structure 12 and the die 13 may be plural.

The substrate 11 can be, for example, a lead frame, for carrying the die 13, which is mainly composed of metal materials such as copper alloy or nickel-iron alloy. A magnetocaloric material is added during the manufacturing process. The amount of addition can be, for example, 1 wt % to 10 wt % of the main material. A copper alloy or a nickel-iron alloy is mixed into the raw material of the substrate 11 by melting; wherein, the magnetocaloric material can be, for example, Gd₂O₃, Gd₅Ge₂Si₂, etc. Preferably, the substrate 11 may include a die seat for positioning the die 13, a plurality of inner pins, and a plurality of outer pins. In practice, the inner pins are encapsulated by the sealing compound 14 while the outer pins are not encapsulated by the sealing compound 14. Both the inner pins and the outer pins belong to a part of the substrate 11.

The two ends of the electrical connection structure 12 are respectively connected with the electrical contacts and the inner pins to form an electrical connection between the die 13 and the external circuit. The electrical connection structure 12 is a metal wire, a conductive metal ball, a film-type pin, etc., which can be correspondingly fabricated by processes such as wire bonding, ball grid array, flip-chip, or tape-automated bonding. However, any method that can realize the electrical connection between the die 13 and the external circuit can be implemented.

The die 13 can be, for example, a bipolar junction transistor (BJT) and field-effect transistor (FET) which completes the fabrication of semiconductor elements and electrodes of an integrated circuit. The die 13 includes a plurality of electrical contacts, which serve as positions where the die 13 is electrically connected to an external circuit.

The sealing compound 14 is formed on the substrate 11 and covers the electrical connection structure 12, the die 13, and the inner pins. The material of the sealing compound 14 can be, for example, epoxy, or a composite material in which epoxy resin is mixed with one or a combination of metal and ceramic materials. The packaging structure 1 with a magnetocaloric material has good impact resistance and weather resistance properties through the sealing compound 14.

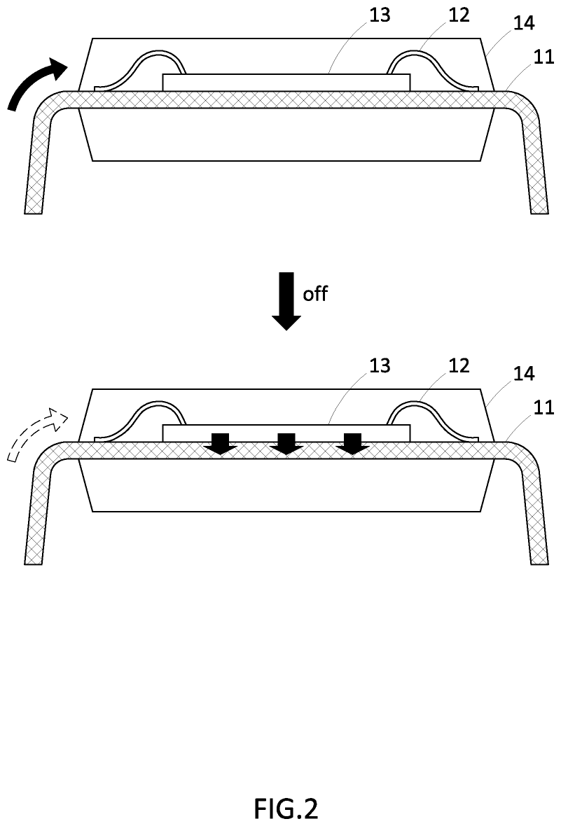

Referring to FIG. 2, the packaging structure 1 with a magnetocaloric material is used to package various integrated circuits. When the packaged integrated circuit is switched on and off, a current flowing into the die 13 from the external circuit through the substrate 11 will induce a magnetic field change. At this time, the magnetocaloric material coated on the substrate 11 will increase the heat dissipation efficiency due to the change of the magnetic field. Specifically, when a magnetic field is induced by passing the current flowing from the substrate 11 into the external circuit, the magnetic moment of the magnetocaloric material in the substrate 11 will be regularly arranged along the direction of the magnetic field. The magnetic entropy and heat capacity of the material will be arranged regularly. In this way, the magnetic entropy and the heat capacity of the material are both reduced such that heat is released simultaneously. The released heat will be dissipated by the substrate 11 through the thermal conduction. When the external current stops flowing into the circuit, the magnetic field induced by the substrate 11 disappears. Meanwhile, the magnetic moment returns to a non-directional state, thereby producing a magnetic refrigeration to effectively reduce the temperature. As a result, not only the heat dissipation effect can be achieved by the magnetic refrigeration, but also the temperature difference between the substrate 11 and the outside can be formed due to the temperature change when the magnetic field is generated and disappeared, so that the heat conduction can be maintained at a high efficiency.

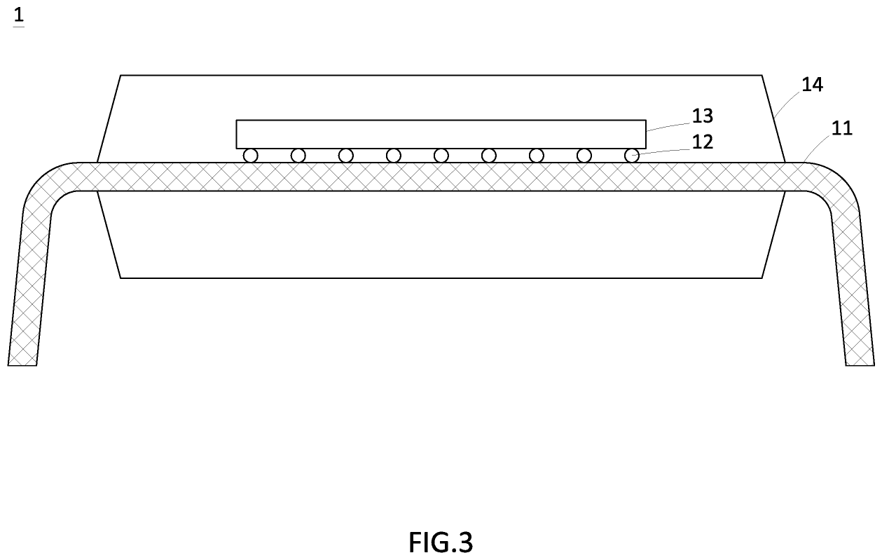

Referring to FIG. 3, the first embodiment takes Flip-chip as an example. As shown in the drawing, the electrical contacts of the die 13 are in a downward state, and a bump is used as the electrical connection structure 12 to complete the electrical connection with the substrate 11. The electrical connection structure 12 and the die 13 are both encapsulated by the sealing compound 14, thus completing the packaging structure 1 with a magnetocaloric material. Moreover, the effect of magnetic refrigeration and heat dissipation can be effectively achieved when each die 13 is switched on/off.

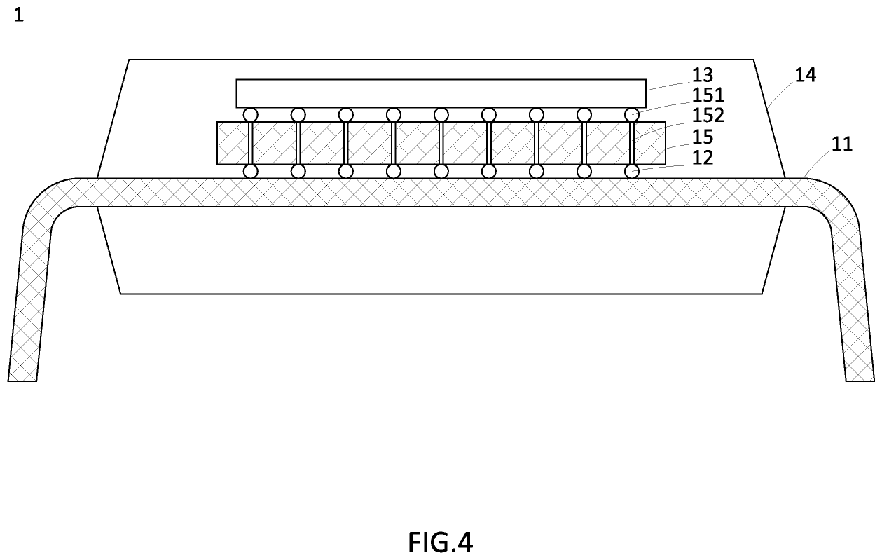

Referring to FIG. 4, the packaging structure 1 with a magnetocaloric material of the present disclosure may include a silicon interposer 15 having a plurality of silicon interposer micro-bumps 151, a plurality of inner metal wires, and a plurality of silicon interposer through holes (TSV) 152. The silicon interposer micro-bumps 151 are used to electrically connect the electrical contacts of each die 13 and the inner metal wire of the silicon interposer 15, so that the silicon interposer 15 can be connected to the electronic signals of different dies 13. Since each inner metal wire is electrically connected to the silicon interposers through holes 152, the silicon interposers through holes 152 are then used to connect the electrical connection structure 12 at the other end of the silicon interposer 15 (shown by the solder bump in this drawing). The electrical connection structure 12 is electrically connected to the substrate 11 with the magnetocaloric material. In addition, the electrical connection structure 12, the die 13, and the silicon interposer 15 are all encapsulated by the sealing compound 14, thus completing the 2.5-dimensional packaging structure 1 with a magnetocaloric material. When each die 13 is switched on/off, the magnetic refrigeration can be effectively achieved.

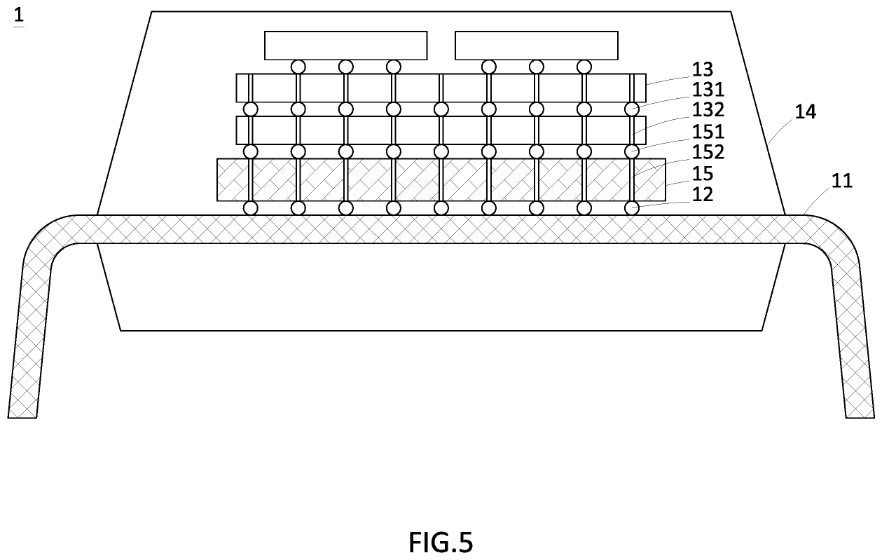

The above-mentioned 2.5-dimensional packaging structure is shown in FIG. 5. Each die 13 includes a plurality of die micro-bumps 131 and a plurality of die through holes 132 that are electrically connected to the electrical contacts. The die micro-bumps 131 are also electrically connected to the die through holes 132. The die 13 can be stacked up and down through the die micro-bumps 131 and electrically connected to each other to complete the stacked structure of the die 13 and to establish the electrical connection to the silicon interposer 15 as depicted above. Meanwhile, the silicon interposer 15 is electrically connected to the substrate 11. The electrical connection structure 12, the die 13, and the silicon interposer 15 are all encapsulated by the sealing compound 14, thereby creating the 3-dimensional packaging structure 1 with a magnetocaloric material. Furthermore, the magnetic refrigeration is achieved when the die 13 are switched on/off.

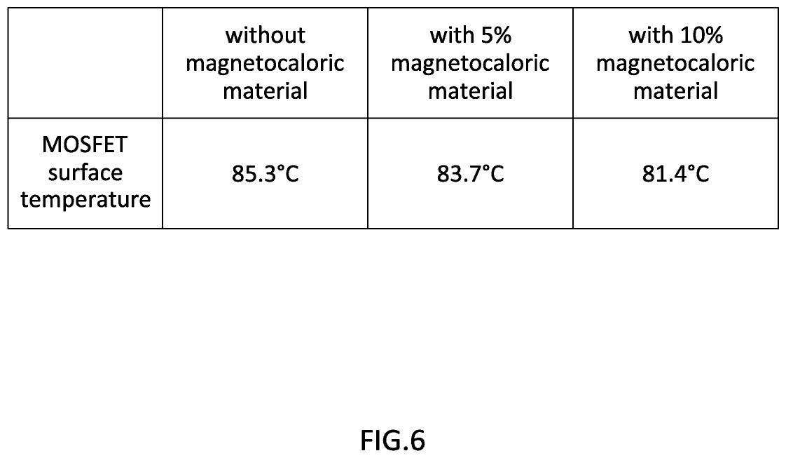

Referring to FIG. 6, the table shows the surface temperature difference when the MOSFET is working in the copper alloy without magnetocaloric material, with 5% magnetocaloric material, and with 10% magnetocaloric material as the substrate composition. It can be seen from the table that when the MOSFET is packaged with a package structure with a magnetocaloric material, it will show a better heat dissipation effect, compared with the packaging structure without adding the magnetocaloric material of the present disclosure to the substrate. Meanwhile, the operating temperature is significantly reduced.

To the summary, the packaging structure with a magnetocaloric material of the present disclosure mainly uses the magnetocaloric material as the raw material of the substrate and uses the magnetic field generated by the external current to change the magnetic moment of the magnetocaloric material. In this way, not only can the magnetic refrigeration effect achieve a good cooling effect, but also the heat dissipation efficiency of the packaging structure can be increased through the temperature difference. The present disclosure can be applied to various mature packaging structures, and can also be applied to the latest forward-looking three-dimensional packaging technology. After the package structure with the magnetocaloric material of the present invention is implemented, the heat dissipation efficiency of the package structure can be effectively improved. Under the conventional packaging structure, the magnetic refrigeration can still be used to improve the heat dissipation efficiency.

### REFERENCE SIGN

1 packaging structure with magnetocaloric material
11 substrate
12 electrical connection structure
13 die
14 sealing compound
131 die micro-bump
132 die through hole
15 silicon interposer
151 silicon interposer micro-bump
152 silicon interposer through hole

What is claimed is:

1. A packaging structure with a magnetocaloric material for packaging a die with a plurality of electrical contacts, comprising:
a substrate composed of a metal material added with a magnetocaloric material, and having a plurality of inner pins;
a plurality of electrical connection structures, two ends of each of the electrical connection structures being respectively disposed on each of the electrical contacts and each of the inner pins, such that the die and the substrate are electrically connected; and
a sealing compound formed on the substrate, the die, the plurality of electrical connection structures, and the inner pins being encapsulated by the sealing compound.

2. The packaging structure with a magnetocaloric material as claimed in claim 1, wherein the magnetocaloric material is one of a gadolinium oxide, a gadolinium-germanium-silicon compound, or a combination thereof.

3. The packaging structure with a magnetocaloric material as claimed in claim 1, wherein the substrate comprises 1 wt % to 10 wt % of the magnetocaloric material.

4. The packaging structure with a magnetocaloric material as claimed in claim 1, wherein the electrical connection structure is one of a metal wire, a conductive metal ball, or a film-type pin.

5. A packaging structure with a magnetocaloric material for packaging a plurality of dies with a plurality of electrical contacts, comprising:
a substrate composed of a metal material added with a magnetocaloric material and having a plurality of inner pins;
a plurality of electrical connection structures, two ends of each of the electrical connection structures being respectively disposed on a silicon interposer and each of the inner pins, such that the plurality of dies are electrically connected to the substrate, wherein the silicon interposer includes a plurality of silicon interposer micro-bumps and a plurality of silicon interposer through holes, and wherein the silicon interposer is electrically connected to each of the dies through the silicon interposer micro-bumps and the silicon interposers through holes; and
a sealing compound formed on the substrate, and wherein the plurality of dies, the plurality of electrical connection structures, the silicon interposer, and the inner pins are encapsulated by the sealing compound.

6. The packaging structure with a magnetocaloric material as claimed in claim 5, wherein the magnetocaloric material is one of a gadolinium oxide, a gadolinium-germanium-silicon compound, or a combination thereof.

7. The packaging structure with a magnetocaloric material as claimed in claim 5, wherein the substrate comprises 1 wt % to 10 wt % of the magnetocaloric material.

8. The packaging structure with a magnetocaloric material as claimed in claim 5, wherein each of the dies comprises a plurality of die micro-bumps and a plurality of die through holes, and wherein the die micro-bumps are electrically connected to the die through holes, and wherein the die micro-bumps are electrically connected to each of the electrical contacts.

9. The packaging structure with a magnetocaloric material as claimed in claim 8, wherein the magnetocaloric material is one of a gadolinium oxide, a gadolinium-germanium-silicon compound, or a combination thereof.

10. The packaging structure with a magnetocaloric material as claimed in claim 8, wherein the substrate comprises 1 wt % to 10 wt % of the magnetocaloric material.
